(19) United States
(12) Patent Application Publication
(10) Pub. No.: US 2017/0040768 A1
(43) Pub. Date: Feb. 9, 2017

(54) Multi-Wavelength Laser Diode Package Arrangement

(71) Applicant: AMD Lasers, Indianapolis, IN (US)

(72) Inventor: Bart Waclawik, Indianapolis, IN (US)

(21) Appl. No.: 14/817,673

(22) Filed: Aug. 4, 2015

(51) Int. Cl. H01S 5/022; H01S 5/40

(52) U.S. Cl. CPC H01S 5/02236; H01S 5/4012; H01S 5/02284; H01S 5/0228; H01S 5/02216; H01S 5/4087; H01S 5/02212

(57) ABSTRACT

A laser diode packaging arrangement for a multi-wavelength and/or multi-power laser apparatus and system. A high-power laser diode module is configured within the packaging arrangement that includes a butterfly or half-butterfly package while one or more laser diodes in a TO-CAN are packaged and configured to provide a single common light output. The TO-CAN diodes can be optically combined with a laser diode mounted inside of the package. The diodes are configured to independently and/or simultaneously emit laser of differing wavelengths and/or power from the same optical output.

### FIELD OF THE DISCLOSURE

The present disclosure relates to laser diode packaging. More specifically, the present disclosure relates to packaging laser diode arrangements to provide a single or multi-wavelength module suitable for use, for example, in a medical laser device.

### BACKGROUND

Light amplification by stimulated emission of radiation, or “LASER”, is a device that creates and amplifies electromagnetic radiation of specific wavelength through process of stimulated emission. In laser devices, all the light rays have three key properties: single wavelength, coherence (they travel in same direction), and same phase.

Lasers have found numerous uses over the years, including industrial applications, measurement and medical applications. Lasers are found in various dental, medical treatment, and surgical applications. Currently, most medical laser systems are developed to provide a single or dual wavelength (e.g. combination of visible and infrared) of the laser energy. In order to use multiple wavelengths for a single device, multiple laser modules are used using a variety of methods for combining the various laser sources into a single delivery system. What is needed is technology for configuring multiple wavelength laser diodes that are packaged in different configurations into an inexpensive laser package with a single fiber-coupled or standard connectorized output (e.g., using fiber connectors).

### SUMMARY

Accordingly, under some illustrative embodiments, a laser package arrangement, that may include a butterfly (BTF) or half-butterfly arrangement, is disclosed comprising a first laser diode module coupled to a bottom portion of a cavity in the laser package arrangement, wherein the first laser diode module is configured to emit laser energy having a first wavelength. A second laser diode module is configured in a transistor outline package, coupled to another portion of the cavity obliquely from the first laser diode module, wherein the second laser diode module is configured to emit laser energy having a second wavelength that is different from the first wavelength. A mirror configured to receive and reflect laser energy from the second laser diode module and an optical output is configured to receive laser energy from the first laser diode and the reflected laser energy.

In other illustrative embodiment, a method is disclosed for forming a laser package arrangement for medical applications, comprising coupling a first laser diode module to a bottom portion of a cavity in the laser package arrangement, wherein the first laser diode module is configured to emit laser energy having a first wavelength. The method may further comprise coupling a second laser diode module, configured in a transistor outline package, to another portion of the cavity obliquely from the first laser diode module, wherein the second laser diode module is configured to emit laser energy having a second wavelength that is different from the first wavelength; coupling a mirror in the cavity of the laser package arrangement to receive and reflect laser energy from the second laser diode module; and coupling an optical output in the laser package arrangement opposite the first laser diode module, wherein the optical output is configured to receive laser energy from the first laser diode and the reflected laser energy.

In still further illustrative embodiment, a laser package arrangement, that may include a butterfly or half-butterfly arrangement, is disclosed for use in a medical application hand-piece, comprising a first laser diode module coupled to a bottom portion of a cavity in the laser package arrangement, wherein the first laser diode module is configured to emit laser energy having a first wavelength. The laser package arrangement may further comprise a second laser diode module, configured in a transistor outline package, coupled to another portion of the cavity obliquely from the first laser diode module, wherein the second laser diode module is configured to emit laser energy having a second wavelength that is different from the first wavelength; a mirror configured to receive and reflect laser energy from the second laser diode module; and an optical output, configured to receive laser energy from the first laser diode and the reflected laser energy and optically communicate the received laser energy and reflected laser energy to the hand-piece.

### BRIEF DESCRIPTION OF THE FIGURES

The present disclosure will become more fully understood from the detailed description given herein below and the accompanying drawings which are given by way of illustration only, and which thus do not limit the present disclosure, and wherein:

FIG. 1 shows a multi-wavelength laser module package having one or more diodes configured on one side of the package and at least one other diode configured on another side of the package under an illustrative embodiment;

FIG. 2 shows a TO-CAN laser comprising a laser diode under an illustrative embodiment suitable for use in the configuration of FIG. 1; and

FIG. 3 shows a BTF butterfly package configuration for use in housing the multi-wavelength laser module package of FIG. 1 under an illustrative embodiment.

### DETAILED DESCRIPTION

The figures and descriptions provided herein may have been simplified to illustrate aspects that are relevant for a clear understanding of the herein described devices, systems, and methods, while eliminating, for the purpose of clarity, other aspects that may be found in typical similar devices, systems, and methods. Those of ordinary skill may thus recognize that other elements and/or operations may be desirable and/or necessary to implement the devices, systems, and methods described herein. But because such elements and operations are known in the art, and because they do not facilitate a better understanding of the present disclosure, a discussion of such elements and operations may not be provided herein. However, the present disclosure is deemed to inherently include all such elements, variations, and modifications to the described aspects that would be known to those of ordinary skill in the art.

Exemplary embodiments are provided throughout so that this disclosure is sufficiently thorough and fully conveys the scope of the disclosed embodiments to those who are skilled in the art. Numerous specific details are set forth, such as examples of specific components, devices, and methods, to provide this thorough understanding of embodiments of the present disclosure. Nevertheless, it will be apparent to those skilled in the art that specific disclosed details need not be employed, and that exemplary embodiments may be embodied in different forms. As such, the exemplary embodiments should not be construed to limit the scope of the disclosure. In some exemplary embodiments, well-known processes, well-known device structures, and well-known technologies may not be described in detail.

The terminology used herein is for the purpose of describing particular exemplary embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The steps, processes, and operations described herein are not to be construed as necessarily requiring their respective performance in the particular order discussed or illustrated, unless specifically identified as a preferred order of performance. It is also to be understood that additional or alternative steps may be employed.

When an element or layer is referred to as being “on”, “engaged to”, “connected to” or “coupled to” another element or layer, it may be directly on, engaged, connected or coupled to the other element or layer, or intervening elements or layers may be present. In contrast, when an element is referred to as being “directly on,” “directly engaged to”, “directly connected to” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another element, component, region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the exemplary embodiments.

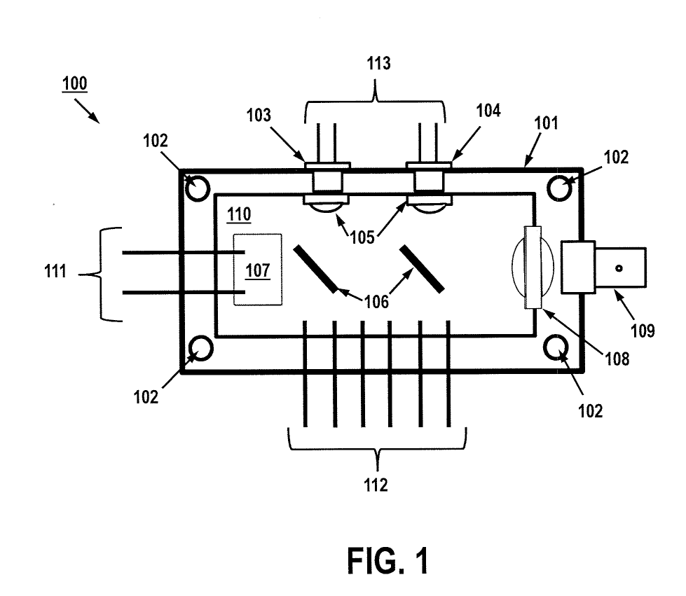

Turning now to FIG. 1, a multi-wavelength laser module package 100 is shown under an illustrative embodiment. In this example, a first diode 107 having external leads 111 is configured across from aspheric lens 108 that provides laser energy to an optical output via fiber connector 109, which may be configured to provide laser energy to a laser hand piece or the like. In one example, laser diode 107 may be a high-current device, such as an infra-red (IR) laser diode with external leads 111 providing a high current anode and cathode connection IR diode 107.

In one embodiment, the laser die for diode 106 may be mounted on a sub-mount of material having a coefficient of thermal expansion (CTE) that matches or is similar to the CTE of the die. In this configuration, the sub-mount may serve as a heat spreader, which may be further mounted onto a thermal electric cooler (TEC) for rapid heat transferring. The entire assembly may then be mounted onto a metal (e.g., copper or copper/tungsten, Kovar™, etc.) heatsink for greater heat dissipation and cooling, and soldered or otherwise affixed to a bottom surface of enclosure 110 that is part of the overall laser housing 101 of multi-wavelength laser module package 100. The laser diode chip may be brazed on the heat sink and the fiber core may be aligned to the output of the laser diode until a maximum light coupling is obtained. In some illustrative embodiments, a regulator may be brazed to the bottom surface of enclosure 100. The laser housing 101, under an illustrative embodiment, may be configured as a BTF “butterfly” (e.g., 14-pin) or “half-butterfly” (e.g., 7-pin) module having mounting holes 102 for attachment within a laser device, such as a medical laser.

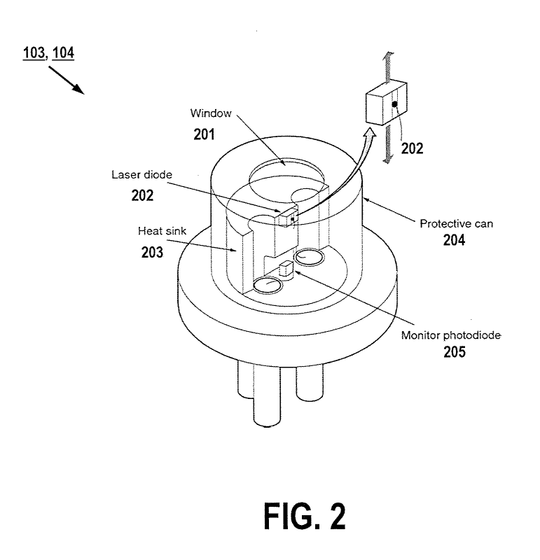

Laser module package 100 may further comprise a second laser diode 103 configured as a transistor outline (“TO-CAN”) package and configured obliquely relative to high power diode 107. An illustrative TO-CAN package is shown in FIG. 2, where laser diode 202 (also show in exploded view in FIG. 2) is coupled to a heat sink 203 and monitor photodiode 205 that may produce current proportional to the output laser diode 202 optical power. As shown in the figure, the laser diode 202, heat sink 203 and monitor photodiode 205 are encased in a protective can 204, with a window 201 configured in the top of protective can 204 to allow laser light to be emitted out. The TO-CAN package may be configured as 5.6 mm or 9 mm diameter. However, it should be appreciated by those skilled in the art that other suitable diameters and powers are contemplated in the present disclosure.

Continuing with the illustrative embodiment of FIG. 1, aspheric lens 105 is configured in front of laser diode 103. The aspheric lenses allows for correction of spherical aberration, which provides better quality collimated beams and a smaller spot size, particularly for medical applications. A further collimator assembly may be provided or integrated with aspheric lens 105 to provide even more focused beams. Laser diode 103 may also be adjustable in the fore and aft positions to provide customized focal lengths and to adjust diode 103 angle relative to higher-powered laser diode 107. The beam emitted from laser diode 103 may then be reflected off of mirror 106 to fiber connector 109, which may be received separately or simultaneously with beams emitted from laser diode 107. In certain embodiments, the laser diodes may be adjustable in at least one of power output, duty cycle, focal position and concentric position.

The configuration of FIG. 1 is particularly advantageous in that laser beams of one wavelength (e.g., from diode 103) and laser beam of another wavelength (e.g., from diode 107) may be provided intermittently and/or simultaneously to the output fiber connector 109. In addition, laser beams of visible and invisible wavelengths (e.g., IR and blue wavelengths) may be provided intermittently and/or simultaneously to the output fiber connector 109. As will be discussed in further detail below, this provides an advantageous laser arrangement for a device (e.g., handpiece) used in medical applications. In another illustrative embodiment, additional laser diodes, such as diode 104 may be provided for even more flexibility and/or customization. In this example, laser diode 104 may be configured similarly to laser diode 103, and direct emitted laser energy through its own aspheric lens 105 and mirror 106 to fiber connector 109. Configuring laser diode 104 to produce a laser beam of yet another wavelength (e.g., violet), laser module package 100 may be capable of providing three different wavelengths (via diode 107, 103 and 104) intermittently and/or simultaneously to fiber connector 109. The timing and/or activation of diodes 103, 104 may be controlled externally via leads 113. It should be appreciated by those skilled in the art that numerous different wavelengths and configurations are contemplated by the present disclosure including addition of diodes to the left or right of 103 and 104.

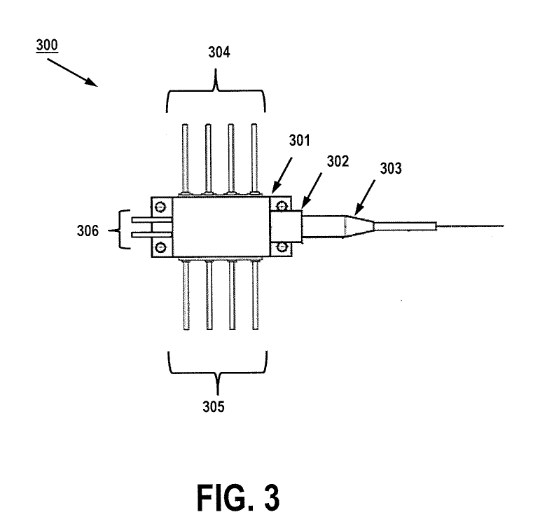

A covered package 300 of FIG. 1 is shown in FIG. 3 under an illustrative embodiment. Multi-wavelength laser module package 300 may be hermetically sealed with high-power leads 306 for providing power to high power lasers or laser modules (e.g., 107), along with low-power leads 304 for providing power to lower-powered lasers or laser modules (e.g., 103, 104). Additional leads or pins 305 may be provided (similar to pins 112) for any other low or high power applications suitable for package 300, including, but not limited to, thermo-electric cooler(s), thermistor(s), ground lead(s), photodiode(s) and further connection to diodes 103, 104 and 107 as needed.

The present disclosure provides a convenient and advantageous configuration for providing multiple lasers of different strengths and wavelengths in a single package, which is very useful in medical applications. Most medical therapy is based on induction of biologic response through energy transfer. In many cases, the emitted wavelength from lasers determines the effective depth of penetration in a patient. In the case of dental lasers, they typically function by producing waves of photons (quanta of light) that are specific to each laser wavelength. This photonic absorption within the target tissue results in an intracellular and/or intercellular change to produce a desired result. When a medium is stimulated by an energy source in a controlled and methodical manner, the light emitted is of a single wavelength particular to the medium (i.e, monochromatic) and is intense or high energy, coherent (travels in a constant phase in time and space), and collimated (travels in the same direction). Such properties enable the light beam to penetrate tissue in order to incise the tissue, seal blood vessels and nerves, and char and vaporize diseased tissue.

Effects of laser are also dependent on the type of laser used, as well as on the type of tissue, since a particular tissue may transmit, absorb, scatter or reflect the laser light. Transmission of energy may not typically have any effect on the tissue but can result in damage to deeper structures. The tendency of tissue to absorb laser energy determines the final effect of the laser. Different wavelengths are absorbed to various extents by different types of tissue, causing the tissue to disintegrate due to heat, chemical reaction, or mechanical disruption.

Under the present disclosure, multi-wavelength laser module package 100 may be configured to provide use of various types of lasers in medical diagnosis, treatment, or therapy. High-power lasers (e.g., 107) may use laser energy to increase tissue kinetic energy and produce heat. As a result, they leave their therapeutic effects through thermal interactions. These effects include necrosis, carbonization, vaporization, coagulation and denaturation. In some illustrative embodiments, the high-power laser may have an output power of more than 500 mW. For lower-power (intermediate) applications (e.g., using diodes 103, 104), therapeutic effects may be provided without producing significant heat. In some illustrative embodiments, the lower-power laser may have an output power ranging from 250-500 mW. For low-power applications (e.g., using diodes 103, 104) the lasers typically will have no thermal effect on tissues and produce a reaction in cells through light, known as photo-biostimulation or photo-biochemical reaction.

In addition to power, laser applications including, but not limited to, incisions, vaporization, or coagulation are determined by the wavelength, the energy fluence, the optical characteristics of the tissues, and how the laser is operated. In continuous mode, the laser provides a constant and stable delivery of energy. Lasers within the ultraviolet region (100 to 380 nm) are able to ionize tissues, a process known as photochemical desorption. Lasers of longer wavelengths, especially those within the infrared part of the spectrum (700 to 10,000 nm), cause significant tissue heating. Additionally, lasers using red, yellow, green, blue, violet and other colors are advantageous for emitting visible electromagnetic radiation, typically in the 360 nm to 600 nm range to target or point a spot on a surface subjected to medical, surgical and/or therapeutic applications. In one non-limiting example, either of laser diodes 103, 104 may be configured to provide an illuminating spot or spots on a surface prior to activating a surgical laser (e.g., 107). As each of these lasers are packed in a single module and illuminate from the same hand piece, such a configuration advantageously mitigates the need for using multiple, bulky, laser arrangements while providing effective and accurate performance.

Accordingly, under the present disclosure, a plurality of lasers may be combined into one package to allow users, particularly in the medical fields, to combine multiple advantageous laser effects including, but not limited to, optical effects (e.g., fluorescence), photomechanical effects (e.g., removal of pigmented lesions), photochemical effects (e.g., photodynamic therapy), photothermal effects (e.g., laser resurfacing, treatment of vascular lesions), and photo-biostimulative and photo-biomodulative effects (e.g., anti-inflammatory treatments, accelerated wound healing).

In the foregoing detailed description, it can be seen that various features are grouped together in individual embodiments for the purpose of brevity in the disclosure. This method of disclosure is not to be interpreted as reflecting an intention that the subsequently claimed embodiments require more features than are expressly recited in each claim.

Further, the descriptions of the disclosure are provided to enable any person skilled in the art to make or use the disclosed embodiments. Various modifications to the disclosure will be readily apparent to those skilled in the art, and the generic principles defined herein may be applied to other variations without departing from the spirit or scope of the disclosure. Thus, the disclosure is not intended to be limited to the examples and designs described herein, but rather are to be accorded the widest scope consistent with the principles and novel features disclosed herein.

1. A laser modular package arrangement comprising:
a first laser diode module on sub-mount coupled to a bottom portion of a cavity in the laser package arrangement, wherein the first laser diode module is configured to emit laser energy having a first wavelength;
a second laser diode module, configured in a transistor outline package, coupled to another portion of the cavity obliquely from the first laser diode module, wherein the second laser diode module is configured to emit laser energy having a second wavelength that is different from the first wavelength, wherein the first wavelength or the second wavelength is a visible wavelength;
a mirror or system of mirrors and associated optics configured to turn and combine laser energy from the second laser diode module to a common single optical output; and
an optical output system, configured to receive laser energy from the first laser diode module and combine it with the laser energy from the second laser diode module and terminate with either a fiber-coupled connection or terminate with a female connector port.

2. The laser package arrangement of claim 1, wherein the laser package arrangement comprises one of a butterfly and a half-butterfly arrangement.

3. The laser package arrangement of claim 1, wherein the first laser diode module is configured to emit laser energy at a higher power than the second laser diode module.

4. The laser package arrangement of claim 1, wherein the optical output is configured to receive laser energy from the first laser diode and the reflected laser energy simultaneously.

5. The laser package arrangement of claim 1, wherein the optical output is configured to receive laser energy from the first laser diode and the reflected laser energy intermittently.

6. The laser package arrangement of claim 1, wherein the second laser diode module is adjustable in its cavity for focal and concentric alignment.

7. The laser package arrangement of claim 1, further comprising
a third laser diode module, configured in a transistor outline package, coupled to another portion of the cavity obliquely from the first laser diode module and laterally from the second laser diode module, wherein the third laser diode module is configured to emit laser energy having a third wavelength that is same or different from the first and second wavelength;
a second mirror configured to receive and reflect laser energy from the third laser diode module, wherein the optical output is configured to receive laser energy from the first laser diode and the reflected laser energy from the mirror and the second mirror.

8. A method for forming a laser package arrangement for medical applications, comprising:
coupling a first laser diode module to a bottom portion of a cavity in the laser package arrangement, wherein the first laser diode module is configured to emit laser energy having a first wavelength;
coupling a second laser diode module, configured in a transistor outline package, to another portion of the cavity obliquely from the first laser diode module, wherein the second laser diode module is configured to emit laser energy having a second wavelength that is same or different from the first wavelength, wherein the first wavelength or the second wavelength is a visible wavelength;
coupling a mirror in the cavity of the laser package arrangement to receive and reflect laser energy from the second laser diode module; and
coupling an optical output in the laser package arrangement opposite the first laser diode module, wherein the optical output is configured to receive laser energy from the first laser diode and the reflected laser energy.

9. The method of claim 8, wherein the laser package arrangement comprises one of a butterfly and a half-butterfly arrangement.

10-12. (canceled)

13. The method of claim 8, wherein coupling the second laser diode module comprises coupling the second laser diode module to be adjustable in one of power output, duty cycle, focal position and concentric position.

14. The method of claim 8, further comprising
coupling a third laser diode module, configured in a transistor outline package, to another portion of the cavity obliquely from the first laser diode module and laterally from the second laser diode module, wherein the third laser diode module is configured to emit laser energy having a third wavelength that is same or different from the first and second wavelength;
coupling a second mirror in the cavity of the laser package arrangement, wherein the second mirror is configured to receive and reflect laser energy from the third laser diode module, wherein the optical output is configured to receive laser energy from the first laser diode module and the reflected laser energy from the mirror and the second mirror.

15. A laser package arrangement for use in a medical application hand piece, comprising:
a first laser diode module coupled to a bottom portion of a cavity in the laser package arrangement, wherein the first laser diode module is configured to emit laser energy having a first wavelength;
a second laser diode module, configured in a transistor outline package, coupled to another portion of the cavity obliquely from the first laser diode module, wherein the second laser diode module is configured to emit laser energy having a second wavelength that is same or different from the first wavelength, wherein the first wavelength or the second wavelength is a visible wavelength;
a mirror configured to receive and reflect laser energy from the second laser diode module; and
an optical output, configured to receive laser energy from the first laser diode module and the reflected laser energy and optically communicate the received laser energy and reflected laser energy to the hand piece.

16. The laser package arrangement of claim 15, wherein the laser package arrangement comprises one of a butterfly and a half-butterfly arrangement.

17-19. (canceled)

20. The laser package arrangement of claim 15, wherein the second laser diode module is adjustable.

21. The laser package arrangement of claim 1, wherein a maximum power of the first laser diode module is greater than 500 mW and a maximum power of the second laser diode module is less than 250 mW.

22. The laser package arrangement of claim 1, wherein the first wavelength or the second wavelength is an infrared wavelength.

23. The laser package arrangement of claim 1, wherein the first wavelength or the second wavelength is an ultraviolet wavelength.

24. The laser package arrangement of claim 1, wherein the laser package arrangement is coupled to a hand piece capable of directing the laser energy of the first laser diode module to target tissue of a patient for use in a medical application.

25. The laser package arrangement of claim 1, wherein the laser package arrangement comprises a half butterfly arrangement, wherein each pin on one side of the laser package arrangement is a pin associated with the second laser diode module or with one or more additional laser diode modules different from the first laser diode module.

26. The method of claim 8, further comprising performing a medical procedure by directing the laser energy of the first laser diode module and the laser energy of the second laser diode module to target tissue of a patient.
